(19) United States
(12) Patent Application Publication
(10) Pub. No.: US 2021/0288140 A1
(43) Pub. Date: Sep. 16, 2021

(54) SEMICONDUCTOR DEVICE AND POWER CONVERTER

(71) Applicant: Mitsubishi Electric Corporation, Tokyo (JP)

(72) Inventor: Yasuo ATA, Tokyo (JP)

(73) Assignee: Mitsubishi Electric Corporation, Tokyo (JP)

(21) Appl. No.: 16/324,967

(22) PCT Filed: Oct. 28, 2016
(86) PCT No.: PCT/JP2016/082070

§ 371 Date: Feb. 12, 2019

(51) Int. Cl. H01L 29/06; H01L 29/78; H01L 29/16; H01L 29/423

(52) U.S. Cl. CPC H01L 29/0657; H01L 29/0619; H01L 29/4236; H01L 29/1608; H01L 29/7811

(57) ABSTRACT

A semiconductor device includes an effective region being a region where a semiconductor element is formed, a chip end portion being an outer peripheral portion of a semiconductor layer, and a withstand voltage holding region disposed between the effective region and the chip end portion. The top of the withstand voltage holding region is covered by a protective film (15) including a first layer (15a) and a second layer (15b) formed on the first layer (15a). The first layer (15a) and the second layer (15b) of the protective film (15) have the same composition. The second layer (15b) is an uppermost layer of the protective film (15) and is formed such that an upper surface of the protective film (15) has a shape having raised portions and recessed portions.

### TECHNICAL FIELD

The present invention relates to a semiconductor device and a power converter, and more particularly to technology for reducing surface discharge.

### BACKGROUND ART

A semiconductor device for electric power control, i.e., a power semiconductor device, is required to hold a high voltage. Therefore, an ineffective region (hereinafter referred to as a “withstand voltage holding region”) for holding a high voltage is disposed between an effective region where a semiconductor element is formed and an end portion of a semiconductor chip (hereinafter referred to as a “chip end portion”). In general, a diffusion layer that distributes a high voltage to hold the high voltage, such as a field limiting ring (FLR) structure, a reduced surface field (RESURF) structure, and a variation of lateral doping (VLD) structure, is formed in the withstand voltage holding region. When such a withstand voltage holding region is disposed in a chip of a semiconductor device, the semiconductor device can hold a high voltage.

However, a large width of the withstand voltage holding region increases the size of the chip, and reduces the number of chips that can be obtained from a single semiconductor wafer, thus increasing chip costs. Therefore, narrowing the withstand voltage holding region has been under discussion. In particular, a silicon carbide (SiC) semiconductor device that is expected as a next-generation power semiconductor device is required to reduce the area of the withstand voltage holding region to reduce the chip size because a SiC wafer is expensive and also has many crystal defects. A reduced chip size can reduce the chip costs and the content ratio of defects. Reduction in the width of the withstand voltage holding region has hitherto been intended using the FLR structure, the RESURF structure, the VLD structure, or the like.

In contrast, a reduced width of the withstand voltage holding region reduces a creepage distance between the chip end portion and the effective region, and thus surface discharge is more liable to be caused between the chip end portion and the effective region. Accordingly, in the semiconductor device having a small width of the withstand voltage holding region, a package sealing member needs to be improved by, for example, mounting the semiconductor device to a resin-molded package using resin having a high dielectric constant in order to reduce surface discharge, which may result in causing increase in costs.

Patent Document 1 below discloses a semiconductor device in which a creepage distance is lengthened by providing a plurality of trenches on an upper surface of a protective film covering a withstand voltage holding region to form raised portions and recessed portions on the upper surface of the protective film. Further, Patent Document 2 discloses a semiconductor device in which raised portions and recessed portions are provided on an upper surface of a protective film by forming a protective film as a double-layer structure consisting of a plasma nitride film and a PSG film on the plasma nitride film, and patterning the PSG film. Patent Document 3 discloses a semiconductor device in which a mesa groove for exposing a PN junction portion is provided around a chip, and a side wall of the mesa groove that exposes the PN junction portion is covered by a protective film.

### PRIOR ART DOCUMENTS

### Patent Documents

Patent Document 1: Japanese Patent Application Laid-Open No. 2014-204067
Patent Document 2: Japanese Patent Application Laid-Open No. 02-119248 (1991)
Patent Document 3: Japanese Patent Application Laid-Open No. 2007-158218

### SUMMARY

### Problem to be Solved by the Invention

The technology of Patent Document 1 has a fear that functions such as securing insulation, stress relaxation, and protection from a foreign matter, which are original functions of the protective film, may be deteriorated because the trenches are formed on the protective film having a single structure. The technology of Patent Document 2 has a problem that external stress cannot be sufficiently relaxed because an adhesion between the plasma nitride film and the PSG film that form the protective film is low. The technology of Patent Document 3 can lengthen a creepage distance; however, since the mesa groove is formed to expose the PN junction portion, there are fears that a foreign matter and mobile ions generated due to etching when the mesa groove is formed may affect the characteristics of the semiconductor device, and the width of a withstand voltage holding region may be reduced more than necessary.

The present invention has been made in order to solve the problems as described above, and has an object to provide a semiconductor device capable of reducing surface discharge between a chip end portion and an effective region while securing original functions of the protective film such as high insulation and stress relaxation.

### Means to Solve the Problem

A semiconductor device according to a first aspect of the present invention includes a semiconductor layer, a semiconductor element formed in the semiconductor layer, an effective region being a region where the semiconductor element in the semiconductor layer is formed, a chip end portion being an outer peripheral portion of the semiconductor layer, a withstand voltage holding region disposed between the effective region and the chip end portion, and a protective film covering the withstand voltage holding region. The protective film includes a first layer, and a second layer formed on the first layer. The first layer and the second layer have the same composition. The second layer is an uppermost layer of the protective film and is formed such that an upper surface of the protective film has a shape having raised portions and recessed portions.

A semiconductor device according to a second aspect of the present invention includes a semiconductor layer, a semiconductor element formed in the semiconductor layer, an effective region being a region where the semiconductor element in the semiconductor layer is formed, a chip end portion being an outer peripheral portion of the semiconductor layer, a withstand voltage holding region disposed between the effective region and the chip end portion, and a protective film covering the withstand voltage holding region. The semiconductor layer of the chip end portion includes a thin portion that is thinner than another portion such that a level difference is formed on an upper surface. An end portion of the protective film close to the chip end portion is located on the thin portion of the semiconductor layer.

### Effects of the Invention

According to the present invention, a creepage distance between the chip end portion and the effective region can be lengthened while original functions of the protective film such as high insulation and stress relaxation are maintained. Therefore, surface discharge between the chip end portion and the effective region can be reduced.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a diagram showing a configuration of a semiconductor device according to a first embodiment.

FIG. 2 is a diagram showing a configuration of a semiconductor device according to a second embodiment.

FIG. 3 is a diagram showing a configuration of a semiconductor device according to a third embodiment.

FIG. 4 is a block diagram showing a configuration of a power conversion system according to a fourth embodiment.

### DESCRIPTION OF EMBODIMENTS

### First Embodiment

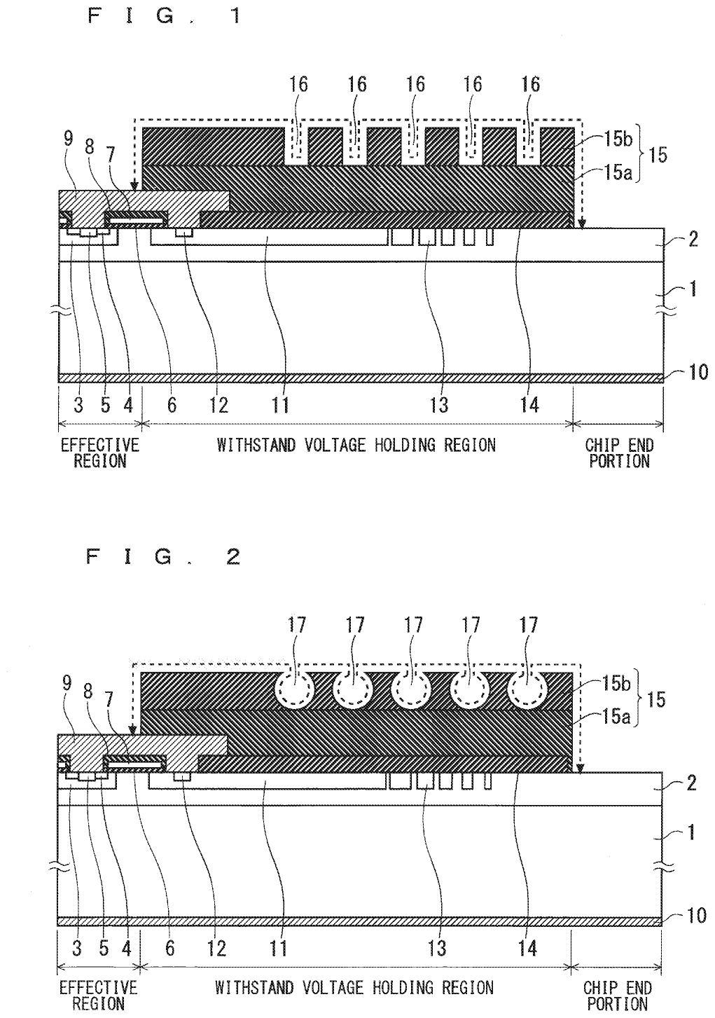

FIG. 1 is a diagram showing a configuration of a semiconductor device according to a first embodiment, and shows a cross-section near an end portion of a semiconductor chip. As in FIG. 1, the semiconductor device is formed by using a semiconductor layer consisting of a semiconductor substrate 1 and an epitaxial layer 2 formed on the semiconductor substrate 1. Further, the semiconductor layer includes an effective region being a region where a semiconductor element is formed, a chip end portion being an outer peripheral portion of the semiconductor chip, and a withstand voltage holding region being a withstand voltage holding region disposed between the effective region and the chip end portion. The withstand voltage holding region and the chip end portion are disposed to surround the effective region.

In this embodiment, an N-type MOSFET is illustrated as an example of the semiconductor element formed in the effective region. In this case, a conductivity type of each of the semiconductor substrate 1 and the epitaxial layer 2 is set to be an N type. Further, here, the semiconductor substrate 1 and the epitaxial layer 2 are made of SiC. Note that the semiconductor element is not limited to the N-type MOSFET, and may be a P-type MOSFET, an IGBT, a diode, or the like. Further, a material of the semiconductor substrate 1 and the epitaxial layer 2 is also not limited to SiC, and may be another wide-bandgap semiconductor (such as gallium nitride (GaN) and diamond). Further, the present invention can also be applied to a semiconductor device using silicon (Si).

In the effective region, a P-type well region 3 is selectively formed in a surface layer portion of the epitaxial layer 2. In the surface layer portion of the well region 3, an N-type source region 4 and a well contact region 5 being a high-concentration P-type region are formed. A portion of the well region 3 interposed between the N-type region of the epitaxial layer 2 and the source region 4 serves as a channel region of the MOSFET.

A gate insulating film 6 is formed on the epitaxial layer 2 so as to cover the top of the channel region, and a gate electrode 7 is formed on the gate insulating film 6. Further, an interlayer insulating film 8 is formed on the gate electrode 7, and a source electrode 9 is formed on the interlayer insulating film 8. The source electrode 9 is connected to the source region 4 and the well contact region 5 through a contact hole formed in the interlayer insulating film 8. Further, a drain electrode 10 is disposed on a lower surface (a back surface) of the semiconductor substrate 1.

In contrast, in the withstand voltage holding region, a P-type termination well region 11 and a P-type FLR 13 formed outside the termination well region 11 are provided on the surface layer portion of the epitaxial layer 2 as a termination structure for holding a voltage. The termination well region 11 is connected the source electrode 9 through a contact hole, and a termination well contact region 12 being a high-concentration P-type region is formed in the connecting portion. Note that, as the termination structure provided in the withstand voltage holding region, a RESURF structure, a VLD structure, a junction termination extension (JTE) structure, or the like may be used other than the FLR structure.

A field insulating film 14 is formed on the epitaxial layer 2 in the withstand voltage holding region, and a protective film 15 made of polyimide or the like is formed on the field insulating film 14 so as to cover the withstand voltage holding region.

In the first embodiment, the protective film 15 has a double-layer structure consisting of a first layer 15a and a second layer 15b. The first layer 15a and the second layer 15b have the same composition. The second layer 15b is an uppermost layer of the protective film 15. Further, trenches 16 are formed on the second layer 15b such that an upper surface of the protective film 15 has raised portions and recessed portions. The trenches 16 can be formed by subjecting the second layer 15b to patterning of photolithography or the like.

Because the second layer 15b has the trenches 16, the upper surface of the protective film 15 has raised portions and recessed portions. Consequently, a creepage distance (indicated by the dotted line in FIG. 1) between the chip end portion and the effective region is lengthened, and thus surface discharge can be reduced between the chip end portion and the effective region. Further, the protective film 15 has a double-layer structure consisting of the first layer 15a and the second layer 15b, and only the second layer 15b on the upper side is subjected to processing to form the trenches 16. Moreover, because the first layer 15a and the second layer 15b have the same composition, a high adhesion can be obtained between the first layer 15a and the second layer 15b. Therefore, original functions of the protective film, such as high insulation and stress relaxation, are highly maintained. Moreover, there is another advantage in that deterioration of the functions in the event of a manufacturing defect can be minimized by allocating separate functions to the first layer 15a and the second layer 15b.

The creepage distance can be further lengthened as the trenches 16 provided on the second layer 15b are deeper. Therefore, as in FIG. 1, it is sufficient that the trenches 16 be formed to reach the upper surface of the first layer 15a. Further, from the viewpoint of lengthening the creepage distance, it is preferred that an extending direction of the trenches 16 be perpendicular to a direction from the chip end portion toward the effective region. However, the shape of the trenches 16 may be any shape as long as the creepage distance can be lengthened. For example, in place of the trenches 16, a plurality of openings having any shape may be provided.

Further, in this embodiment, the protective film 15 has a double-layer structure consisting only of the first layer 15a and the second layer 15b; however, the protective film 15 may have a multi-layer structure including three or more layers as long as the first layer 15a and the second layer 15b are included in an uppermost layer portion.

### Second Embodiment

FIG. 2 is a diagram showing a configuration of a semiconductor device according to a second embodiment, and shows a cross-section near an end portion of a semiconductor chip. In FIG. 2, components having functions similar to the functions of the components shown in FIG. 1 are denoted by the same reference symbols. In comparison with FIG. 1, the configuration of the semiconductor device of FIG. 2 is different only in the structure of the protective film 15, and other part is the same.

Also in the second embodiment, the protective film 15 has a double-layer structure consisting of the first layer 15a and the second layer 15b having the same composition, and the second layer 15b is formed in a shape in which the upper surface of the protective film 15 has raised portions and recessed portions. Note that, instead of the trenches 16, voids 17 opened on the upper surface of the second layer 15b are formed in the second layer 15b.

The voids 17 can be naturally generated inside the second layer 15b by forming the second layer 15b under a condition in which voids are easily generated. Further, the voids 17 can be opened on the upper surface of the second layer 15h by removing a surface portion of the second layer 15b in an etching process for patterning the protective film 15. Thus, without performing processing on the first layer 15a and the second layer 15b to have different patterns, raised portions and recessed portions can be formed on the upper surface of the protective film 15, and the creepage distance between the chip end portion and the effective region can be lengthened. Note that, in order to secure original functions of the protective film such as high insulation and stress relaxation, it is preferred that the first layer 15a be formed under a condition in which voids are not easily generated.

Because the second layer 15b has the voids 17 opened on the upper surface of the second layer 15b, the upper surface of the protective film 15 has raised portions and recessed portions. Consequently, the creepage distance between the chip end portion and the effective region (indicated by the dotted line in FIG. 2) is lengthened, and surface discharge can be reduced between the chip end portion and the effective region. Further, the protective film 15 has a double-layer structure consisting of the first layer 15a and the second layer 15b, and the voids 17 are formed only on the second layer 15b on the upper side. Moreover, because the first layer 15a and the second layer 15b have the same composition, a high adhesion can be obtained between the first layer 15a and the second layer 15b. Therefore, original functions of the protective film such as high insulation and stress relaxation are highly maintained. Moreover, there is another advantage in that deterioration of the functions in the event of a manufacturing defect can be minimized by allocating separate functions to the first layer 15a and the second layer 15b.

The creepage distance can be further lengthened as the voids 17 opened on the upper surface of the second layer 15b are deeper. Therefore, as in FIG. 2, it is sufficient that a bottom portion of the voids 17 be formed to reach a bottom portion of the second layer 15b. Specifically, it is preferred that the size of the voids 17 be equal to the thickness of the first layer 15a.

### Third Embodiment

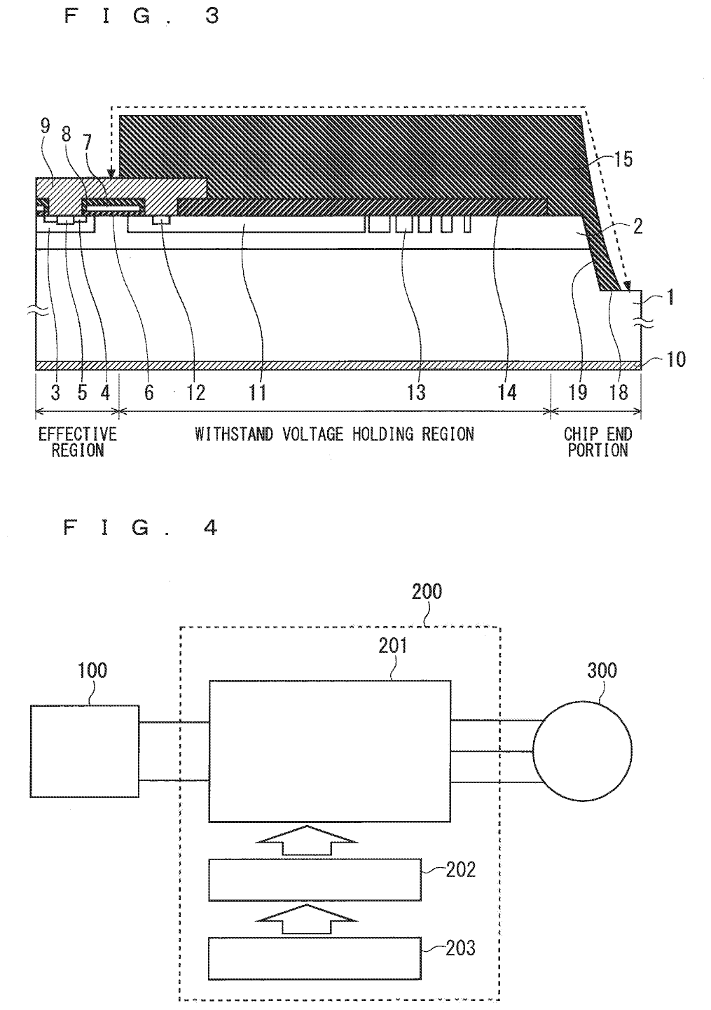

FIG. 3 is a diagram showing a configuration of a semiconductor device according to a third embodiment, and shows a cross-section near an end portion of a semiconductor chip. In FIG. 3, components having functions similar to the functions of the components shown in FIG. 1 are denoted by the same reference symbols. In comparison with FIG. 1, the configuration of the semiconductor device of FIG. 3 is different only in the structure of the chip end portion and the structure of the protective film 15, and other part is the same. Further, in this embodiment, the protective film 15 has a single-layer structure.

As in FIG. 3, in the semiconductor device of the third embodiment, the semiconductor layer (the semiconductor substrate 1 and the epitaxial layer 2) in the chip end portion has a thin portion 18 that is thinner than the semiconductor layer in another portion (hereinafter simply referred to as a “thin portion 18” in some cases). With this, a level difference portion 19 is formed on the upper surface of the semiconductor layer in the chip end portion. Further, the protective film 15 covering the withstand voltage holding region covers the level difference portion 19, and an outer end portion of the protective film 15 is located on the thin portion 18.

In this manner, a thickness (height) difference is provided between the chip end portion and the effective region, and the outer end portion of the protective film 15 is located on the thin portion 18 in the chip end portion. Consequently, the creepage distance between the chip end portion and the effective region (indicated by the dotted line in FIG. 3) can be lengthened, and surface discharge can be reduced between the chip end portion and the effective region. Further, the protective film 15 need not be subjected to a special process, and therefore original functions of the protective film such as high insulation and stress relaxation are highly maintained. Note that, if the protective film 15 having the double-layer structure illustrated in the first or second embodiment is used as the protective film 15, the creepage distance between the chip end portion and the effective region can be further lengthened.

In this embodiment, unlike Patent Document 3 of the above, the level difference portion 19 is provided in the chip end portion without a PN junction portion, and the PN junction portion is not exposed in the level difference portion 19. Therefore, problems that a foreign matter and mobile ions generated due to etching when the level difference portion 19 is formed affect the characteristics of the semiconductor device, and the width of the withstand voltage holding region is reduced more than necessary are not caused.

Moreover, it is preferred that the level difference portion 19 be inclined, that is, a side surface of the level difference portion 19 be inclined with respect to a direction that is perpendicular to the upper surface of the epitaxial layer 2. With the same depth of the level difference portion 19 (the level difference between the epitaxial layer 2 and the thin portion 18) and the same width of the thin portion 18, a longer creepage distance can be secured when the level difference portion 19 is inclined than when the level difference portion 19 is upright.

Particularly, the third embodiment is effective when the semiconductor substrate 1 is made of SiC. Usually, the semiconductor substrate 1 made of SiC is thick, and thus the depth of the level difference portion 19 is easily increased. Therefore, the creepage distance in the vertical direction between the chip end portion and the effective region can be easily lengthened.

### Fourth Embodiment

In this embodiment, the semiconductor device according to the first to third embodiments described above is used in a power converter. Although the present invention is not limited to a specific power converter, a case in which the present invention is applied to a three-phase inverter is described below as a fourth embodiment.

FIG. 4 is a block diagram showing a configuration of a power conversion system using a power converter according to this embodiment.

The power conversion system shown in FIG. 4 includes a power supply 100, a power converter 200, and a load 300. The power supply 100 is a DC power supply, and supplies DC power to the power converter 200. The power supply 100 may be formed of various elements, and may be formed of, for example, a DC system, a solar cell, or a storage battery, or may be a rectifier circuit or an AC/DC converter connected to an AC system. Further, the power supply 100 may be formed of a DC/DC converter that converts DC power output from a DC system into predetermined power.

The power converter 200 is a three-phase inverter connected between the power supply 100 and the load 300, and converts DC power supplied from the power supply 100 into AC power to supply the AC power to the load 300. As shown in FIG. 4, the power converter 200 includes a main converter circuit 201 that converts DC power into AC power to output the AC power, a drive circuit 202 that outputs drive signals for driving switching elements of the main converter circuit 201, and a control circuit 203 that outputs a control signal for controlling the drive circuit 202 to the drive circuit 202.

The load 300 is a three-phase electric motor driven by AC power supplied from the power converter 200. Note that the load 300 is not limited to a specific purpose. The load 300 is an electric motor mounted to various electrical devices, and is used as, for example, an electric motor for a hybrid car, an electric car, a railway vehicle, an elevator, or an air conditioner.

Now, the details of the power converter 200 are described. The main converter circuit 201 includes switching elements and freewheeling diodes (not shown). When the switching elements are switched, DC power supplied from the power supply 100 is converted into AC power, and the AC power is supplied to the load 300. Although there are various specific circuit configurations for the main converter circuit 201, the main converter circuit 201 according to this embodiment is a two-level three-phase full bridge circuit, and can be formed of six switching elements and six freewheeling diodes that are connected to the respective switching elements in anti-parallel. The semiconductor device according to any one of the first to third embodiments described above is used as each switching element of the main converter circuit 201. Every two switching elements of the six switching elements are connected in series to form upper and lower arms, and the upper and lower arms form respective phases (U-phase, V-phase, and W-phase) of the full bridge circuit. Further, output terminals of the upper and lower arms, i.e., three output terminals of the main converter circuit 201, are connected to the load 300.

The drive circuit 202 produces drive signals for driving the switching elements of the main converter circuit 201, and supplies the drive signals to control electrodes of the switching elements of the main converter circuit 201. Specifically, in accordance with a control signal of the control circuit 203 described below, a drive signal for turning on a switching element and a drive signal for turning off a switching element are output to the control electrodes of the respective switching elements. When the switching element is maintained to be turned on, the drive signal is a voltage signal (an on-signal) of a threshold voltage of the switching element or higher. When the switching element is maintained to be turned off, the drive signal is a voltage signal (an off-signal) of the threshold voltage of the switching element or lower.

The control circuit 203 controls the switching elements of the main converter circuit 201 such that desired power is supplied to the load 300. Specifically, time (on-time) at which each switching element of the main converter circuit 201 should be turned on is calculated based on power that should be supplied to the load 300. For example, the main converter circuit 201 can be controlled by PWM control that modulates the on-time of each switching element in accordance with a voltage that should be output. Then, a control command (a control signal) is output to the drive circuit 202 such that the on-signal is output to a switching element that should be turned on, and the off-signal is output to a switching element that should be turned off at respective time points. In accordance with the control signal, the drive circuit 202 outputs the on-signal or the off-signal to the control electrodes of the respective switching elements as the drive signals.

In the power converter according to this embodiment, the semiconductor devices according to the first to third embodiments are used as the switching elements of the main converter circuit 201. Therefore, a low-cost power converter can be achieved.

In this embodiment, an example in which the present invention is applied to a two-level three-phase inverter is described. However, the present invention is not limited thereto, and can be applied to various power converters. In this embodiment, a two-level power converter is used, but a three-level or multi-level power converter may be used, and the present invention may be applied to a single-phase inverter when power is supplied to a single-phase load. Further, the present invention may be applied to a DC/DC converter or an AC/DC converter when power is supplied to a DC load or the like.

Further, the power converter to which the present invention is applied is not limited to the case in which the above-mentioned load is an electric motor. For example, the power converter to which the present invention is applied may be used as a power supply device for an electric discharge machine, a laser beam machine, an induction heating cooking device, and a non-contact power supply system, and may also be used as a power conditioner for a photovoltaic generation system, a power storage system, or the like.

Note that, in the present invention, each of the embodiments may be freely combined, and each of the embodiments may be modified or omitted as appropriate within the scope of the invention.

While the invention has been shown and described in detail, the foregoing description is in all aspects illustrative and not restrictive. It is therefore understood that numerous unillustrated modifications can be devised without departing from the scope of the invention.

### EXPLANATION OF REFERENCE SIGNS

1 semiconductor substrate, 2 epitaxial layer, 3 well region, 4 source region, 5 well contact region, 6 gate insulating film, 7 gate electrode, 8 interlayer insulating film, 9 source electrode, 10 drain electrode, 11 termination well region, 12 termination well contact region, 13 FLR, 14 field insulating film, 15 protective film, 15a first layer, 15b second layer, 16 trench, 17 void, 18 thin portion of semiconductor layer, 19 level difference portion, 100 power supply, 200 power converter, 201 main converter circuit, 202 drive circuit, 203 control circuit, 300 load

1. A semiconductor device comprising:
a semiconductor layer;
a semiconductor element formed in the semiconductor layer;
an effective region being a region where the semiconductor element in the semiconductor layer is formed;
a chip end portion being an outer peripheral portion of the semiconductor layer;
a withstand voltage holding region disposed between the effective region and the chip end portion; and
a protective film covering the withstand voltage holding region, wherein
the protective film comprises a first layer, and a second layer formed on the first layer,
the first layer and the second layer have the same composition, and
the second layer is an uppermost layer of the protective film and is formed such that an upper surface of the protective film has a shape having raised portions and recessed portions.

2. The semiconductor device according to claim 1, wherein
the second layer comprises a trench or an opening.

3. The semiconductor device according to claim 2, wherein
the trench or the opening reaches an upper surface of the first layer.

4. The semiconductor device according to claim 1, wherein
the second layer comprises a void opened on an upper surface of the second layer.

5. The semiconductor device according to claim 4, wherein
a bottom portion of the void reaches a bottom portion of the second layer.

6. A semiconductor device comprising:
a semiconductor layer;
a semiconductor element formed in the semiconductor layer;
an effective region being a region where the semiconductor element in the semiconductor layer is formed;
a chip end portion being an outer peripheral portion of the semiconductor layer;
a withstand voltage holding region disposed between the effective region and the chip end portion; and
a protective film covering the withstand voltage holding region, wherein
the semiconductor layer in the chip end portion comprises a thin portion that is thinner than another portion such that a level difference is formed on an upper surface, and
an end portion of the protective film close to the chip end portion is located on the thin portion of the semiconductor layer.

7. The semiconductor device according to claim 6, wherein
a side surface of the level difference in the chip end portion is inclined.

8. The semiconductor device according to claim 1, wherein
the semiconductor layer is made of silicon carbide.

9. A power converter comprising:
a main converter circuit that converts input power to output the converted power, the main converter circuit comprising the semiconductor device of claim 1;
a drive circuit that outputs a drive signal for driving the semiconductor device to the semiconductor device; and
a control circuit that outputs a control signal for controlling the drive circuit to the drive circuit.

10. The semiconductor device according to claim 6, wherein
the semiconductor layer is made of silicon carbide.

11. A power converter comprising:
a main converter circuit that converts input power to output the converted power, the main converter circuit comprising the semiconductor device of claim 6;
a drive circuit that outputs a drive signal for driving the semiconductor device to the semiconductor device; and
a control circuit that outputs a control signal for controlling the drive circuit to the drive circuit.
